(19) United States
(12) Patent Application Publication
(10) Pub. No.: US 2012/0090682 A1
(43) Pub. Date: Apr. 19, 2012

(54) Solar Cell and Manufacturing Method Thereof

(75) Inventors: Dong Joon Oh, Busan (KR); Hae Seok Lee, Yongin-si (KR); Eun Joo Lee, Seongnam-si (KR); Hyun Woo Lee, Seoul (KR); Jun Young Choi, Siheung-si (KR); Ji Myung Shim, Incheon (KR); Kyeong Yeon Cho, Yongin-si (KR); Ji Sun Kim, Seoul (KR)

(73) Assignee: SHIN SUNG HOLDINGS CO., LTD., Seongnam-si (KR)

(21) Appl. No.: 12/906,562

(22) Filed: Oct. 18, 2010

(51) Int. Cl. H01L 31/0232; H01L 31/0236

(52) U.S. Cl. 136/259; 438/71; 257/E31.13

(57) ABSTRACT

A solar cell and a manufacturing method thereof are provided. The method includes forming a microstructure including a texturing on the surface of a semiconductor substrate of a first conductive type, forming a plurality of nanostructures on the surface of the semiconductor substrate, forming an emitter layer by implanting impurities of a second conductive type opposite to the first conductive type in a front face of the semiconductor substrate, forming an anti-reflective coating (ARC) on the emitter layer, forming a front electrode passing through a portion of the ARC and being coupled to the emitter layer, and forming a back electrode on a rear face of the semiconductor substrate of the first conductive type, the rear face being opposite to the face on which the front electrode is formed. A dominant light-collecting characteristic can be approached by forming nanostructures on a semiconductor substrate of a solar cell.

### BACKGROUND

1. Field of the Invention

The present invention relates to a solar cell and a manufacturing method thereof, and more particularly, to a solar cell and a manufacturing method thereof, which are capable of reducing reflectance of solar light regardless of a wavelength region of solar light.

2. Discussion of Related Art

In recent years, with prediction of exhaustion of existing energy resources such as oil and coal, more attention is being paid to exploitation of alternative energy resources. Among the alternative energy resources, solar cells are being significantly considered because the solar cells may utilize abundant solar energy and be free from environmental pollution. Solar cells may be classified into solar heat cells configured to generate steam required for rotating a turbine using solar heat and into solar light cells configured to convert photons into electric energy using the properties of semiconductor materials. In general, solar cells may be called solar light cells (hereinafter, referred to as ‘solar cells’).

FIG. 1 is a schematic view illustrating a basic structure of a solar cell.

Referring to FIG. 1, the solar cell may have a junction structure between a p-type semiconductor layer 101 and an n-type semiconductor layer 102 like a diode. When light is incident to the solar cell, negative (−) charges (or electrons) and positive (+) charges (or holes) got by emitting electrons may be generated and moved due to interaction between the light and materials constituting the semiconductor layers 101 and 102, thereby obtaining the flow of current. The above-described phenomenon may be referred to as a photovoltaic effect. By the photovoltaic effect, electrons of the p-type and n-type semiconductor layers 101 and 102 may be attracted toward the n-type semiconductor layer 102, while holes thereof may be attracted toward the p-type semiconductor layer 101. As a result, the electrons and the holes may move to electrodes 103 and 104 bonded to the n-type and p-type semiconductor layers 101 and 102, respectively. By connecting the electrodes 103 and 104 using electric wires, the flow of electricity may be enabled to generate electric power.

To increase the efficiency of the solar cell, substantially increasing the number of photons reaching an active layer of the solar cell and substantially reducing loss caused by light reflected by the surface of the solar cell may be very important.

For example, a silicon (Si) layer may undergo texturing to reduce the reflectance of light incident to a front surface of the solar cell and to increase the length of light passing through the solar cell, so as to facilitate absorption of light in the solar cell. In another case, an anti-reflective coating (ARC) may be formed on a substrate to reduce the reflectance of light.

Generally, a polished surface of the substrate may reflect about 30 to 50% of incident solar light, while a pyramidally textured surface of the substrate may reflect about 10 to 20% of incident solar light, thereby markedly reducing the reflectance of solar light. Also, it is known that deposition of an anti-reflective coating (hereinafter, referred to as ‘ARC’) may lead to reduction of the reflectance of light to about 5 to 10%.

However, the reflectance may a mean value observed from 500 nm to 1000 nm as a main absorption wavelength band of solar light, and a short wavelength region of solar light from 300 nm to 400 nm has a relatively high reflectance. Therefore, it may be an issue to be solved that after the deposition of ARC, a relatively low reflectance can be obtained.

Accordingly, those who are skilled in the related field have steadily exerted their efforts to obtain semiconductor substrates having a uniformly and relatively low reflectance on all wavelength regions.

### SUMMARY OF THE INVENTION

It is therefore, provided that the present invention is directed to a solar cell and a manufacturing method thereof, for which all of wavelength regions of solar light have a uniformly and relatively low reflectance.

According to an embodiment of the present invention, a method of manufacturing a solar cell comprises forming a microstructure including a texturing on the surface of a semiconductor substrate of a first conductive type, forming a plurality of nanostructures on the surface of the semiconductor substrate, forming an emitter layer by implanting impurities of a second conductive type opposite to the first conductive type in a front face of the semiconductor substrate, forming an ARC on the emitter layer, forming a front electrode passing through a portion of the ARC and being coupled to the emitter layer, and forming a back electrode on a rear face of the semiconductor substrate of the first conductive type, the rear face being opposite to the face on which the front electrode is formed.

The forming of the nanostructures may be performed to form nanotips by using a deep reactive ion etching (DRIE). The forming of the nanostructure may be performed to form silicon nanotips by consecutively twice performing the DRIEs.

The forming of the nanostructure may comprise covering a front face of the semiconductor substrate with a photosensitive layer and forming the photosensitive layer thereon, molding the photosensitive layer in a given shape by selectively exposing the photosensitive layer to ultraviolet rays, and performing a first deep reactive ion etching by using deposition gas and etching gas and forming nanotips on one face of the semiconductor substrate. The forming of the nanostructure may further comprise removing the photosensitive layer, and performing a second deep reactive ion etching by using deposition gas and etching gas and forming nanotips on one face of the semiconductor substrate.

The nanostructure may be made of silicon material.

The first deep reactive ion etching may be performed to form a scallop of wave pattern on the semiconductor substrate.

The second deep reactive ion etching may be performed to form nanotips on the semiconductor substrate.

The deposition gas may contain C₄F₈ gas.

The etching gas may contain SF₆ gas.

The ARC may contain silicon nitride.

The ARC may be formed via a plasma enhanced chemical vapor deposition (PECVD).

The front and back electrodes may be formed by a printing.

According to an embodiment of the present invention, a dominant light collecting characteristic may be obtained by forming nanostructures on a semiconductor substrate of a solar cell.

In addition, according to an embodiment of the present invention, a uniformly and relatively low reflectance may be obtained on all of wavelength regions of a solar cell, thereby increasing an efficiency of solar cell.

### BRIEF DESCRIPTION OF THE DRAWINGS

The above and other objects, features and advantages of the present invention will become more apparent to those of ordinary skill in the art by describing in detail embodiments thereof with reference to the accompanying drawings, in which:

FIG. 1 is a schematic view illustrating a basic structure of a solar cell; and

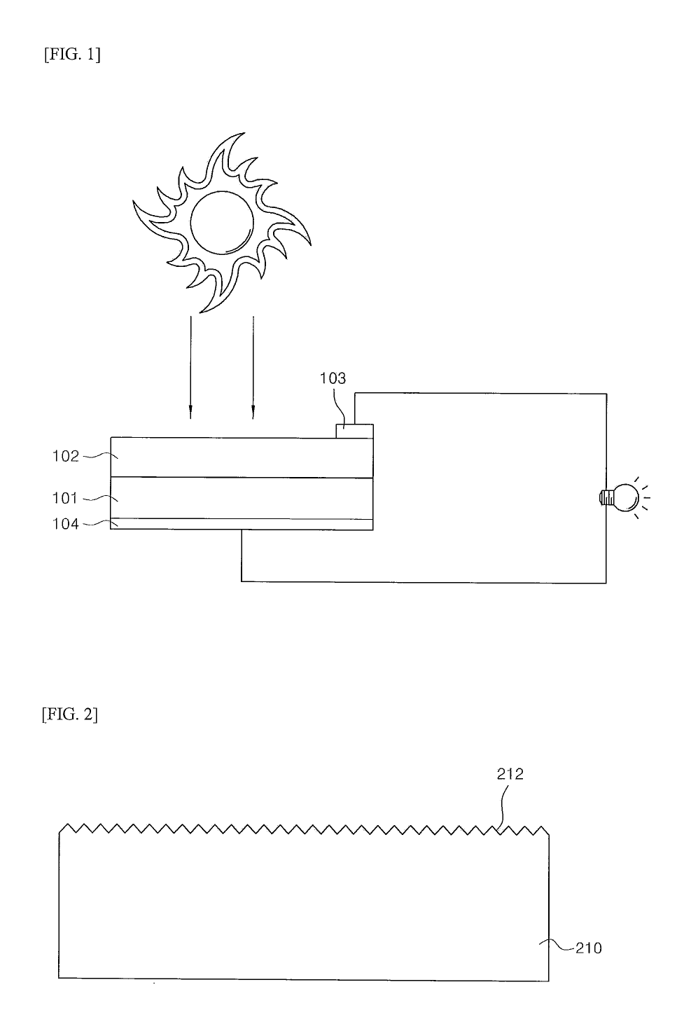

FIGS. 2 to 4 are sectional views illustrating manufacturing processes of a solar cell according to an embodiment of the present invention.

### DETAILED DESCRIPTION OF THE EMBODIMENTS

Embodiments of the present invention will be described in detail below with reference to the accompanying drawings. To facilitate understanding, identical reference numerals are used, where possible, to designate identical elements that are common to the figures. Descriptions of well-known components and processing techniques are omitted so as not to unnecessarily obscure the embodiments of the present invention. The present invention will now be described more fully with reference to the accompanying drawings, in which embodiments of the invention are shown.

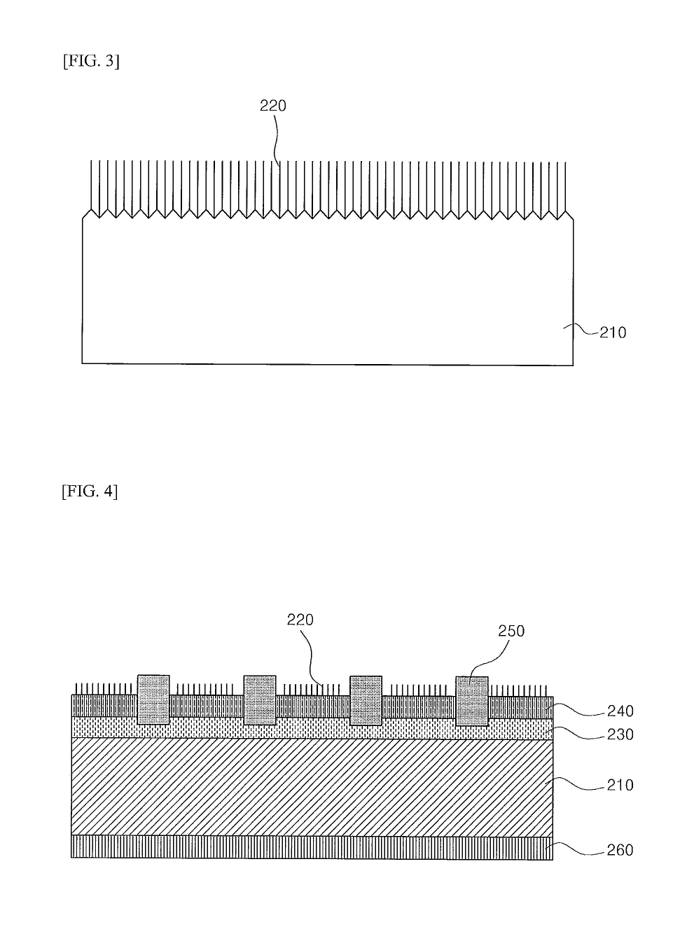

FIGS. 2 to 4 are sectional views illustrating manufacturing processes of a solar cell according to an embodiment of the present invention.

FIG. 2 illustrates a semiconductor substrate 210 having texturing performed on the surface 212 thereof. The texturing may be performed by etching the surface of the semiconductor substrate 210. The surface 212 after the texturing according to one embodiment of the present invention may be formed in a pyramid shape or square honeycomb structure.

FIG. 3 illustrates a plurality of nanostructures 220 formed on the surface of the semiconductor substrate 210. The nanostructures 220 may be made of silicon material according to an embodiment of the present invention.

The formation of the nanostructure 220 according to the embodiment of the present invention may be performed via a process of forming nanotips using a DRIE.

To manufacture patterned silicon nanotips according to an embodiment of the present invention, the basic technology of semiconductor manufacturing processes such as a photo process, layer covering process, DRIE etc., may be employed. The DRIE is called a bosch process. The DRIE may be performed to etch silicon in a vertical direction by repeatedly carrying out a protection polymer deposition using deposition gas, i.e., C₄F₈ gas, and a polymer and silicon etching using etching gas, i.e., SF₆ gas. This process may result in a formation of scallop having fine wave pattern on a sidewall. Nanotips and nanowall are generated as the polymer layer deposited on the sidewall via the DRIE serves as a passivation from the etching, thereby forming scallop on the surface.

According to an embodiment of the present invention, silicon nanotips may be formed by consecutively twice performing the DRIEs. The detailed description is as follows.

A method of manufacturing nanotips may comprise covering a photosensitive layer, molding the photosensitive layer, performing a first DRIE, removing the photosensitive layer, and performing a second DRIE.

The covering of the photosensitive layer may be performed to cover a front face of the semiconductor substrate 210 with a photosensitive layer. The photosensitive layer is formed on one face of the semiconductor substrate 210 via the covering process of the photosensitive layer.

The molding of the photosensitive layer molding may be a photo process to mold the photosensitive layer in a given shape as a desired pattern by selectively exposing the photosensitive layer to ultraviolet rays, X-rays or electron beam. The photosensitive layer may be molded in a given shape via the molding process of the photosensitive layer.

The first DRIE may be performed to form a scallop by etching the semiconductor substrate 210 using deep reactive ions and then to form nanotips on the semiconductor substrate 210. For example, when etching gas such as SF₆ etc. is sprayed to one face of the semiconductor substrate 210 and radio frequency (RF) power is applied thereto, the etching gas of SF₆ is transited to the plasma state and the semiconductor substrate 210 is etched. When after the semiconductor substrate 210 is etched, deposition gas such as C₄F₈ etc. is sprayed and RF power is applied, a protection polymer layer is deposited on an etching portion of the semiconductor substrate 210. When the etching gas is again sprayed to the etching portion and the RF power is applied, the protection polymer layer adapted on the bottom of the etching portion is removed and the semiconductor substrate 210 is again etched. Through the repetitive processes described above, scallop of wave pattern is formed in a depth direction of the semiconductor substrate 210.

The removing of the photosensitive layer may be performed to remove the photosensitive layer remaining on one face of the semiconductor substrate 210. When etching gas is continuously sprayed and becomes ionized plasma, the photosensitive layer is also etched. The removing of the photosensitive layer is the process to remove a photosensitive layer left as being not etched.

The second DRIE may be performed by repeatedly implementing the DRIE on the semiconductor substrate 210 from which the photosensitive layer has been removed. When the etching and deposition are repeated via the second DRIE on the semiconductor substrate 210, nanotips are formed.

Referring to FIG. 4, impurities of a second conductive type opposite to the first conductive type is implanted in a front face of the semiconductor substrate 210 of the first conductive type, thereby forming an emitter layer 230 and thus forming a p-n junction.

An ARC 240 is formed on the emitter layer 230. The ARC 240 may contain silicon nitride according to an embodiment of the present invention. Further, the ARC 240 may be formed via a plasma enhanced chemical vapor deposition (PECVD).

Subsequently, a front electrode 250 is connected to the emitter layer 230, passing through a portion of the ARC 240. The front electrode 250 may be formed by a printing according to an embodiment of the present invention. A back electrode 260 is formed on the rear of the semiconductor substrate 210 of the first conductive type, the rear being the face opposite to the face on which the front electrode 250 is formed. The back electrode 260 may be formed by a printing according to an embodiment of the present invention.

According to the embodiment of the present invention, it does not matter to change the sequence of forming the front electrode 250 and forming the back electrode 260.

It will be apparent to those skilled in the art that various modifications can be made to the above-described embodiments of the present invention without departing from the spirit or scope of the invention. Thus, it is intended that the present invention covers all such modifications provided they come within the scope of the appended claims and their equivalents.

1. A method of manufacturing a solar cell, comprising:
forming a microstructure including a texturing on the surface of a semiconductor substrate of a first conductive type;
forming a plurality of nanostructures on the surface of the semiconductor substrate;
forming an emitter layer by implanting impurities of a second conductive type opposite to the first conductive type in a front face of the semiconductor substrate;
forming an anti-reflective coating (ARC) on the emitter layer;
forming a front electrode passing through a portion of the ARC and being connected to the emitter layer; and
forming a back electrode on a rear face of the semiconductor substrate of the first conductive type, the rear face being opposite to the face on which the front electrode is formed.

2. The method of claim 1, wherein forming the nanostructures is performed to form nanotips by using a deep reactive ion etching (DRIE).

3. The method of claim 2, wherein forming the nanostructure is performed to form silicon nanotips by consecutively twice performing the DRIEs.

4. The method of claim 2, wherein forming the nanostructure comprises:
covering the front face of the semiconductor substrate with a photosensitive layer and forming the photosensitive layer thereon;
forming the photosensitive layer in a given shape by selectively exposing the photosensitive layer to ultraviolet rays; and
performing a first DRIE and forming nanotips on one face of the semiconductor substrate by using deposition gas and etching gas.

5. The method of claim 4, wherein forming the nanostructure further comprises:
removing the photosensitive layer; and
performing a second DRIE by using deposition gas and etching gas, and forming nanotips on one face of the semiconductor substrate.

6. The method of claim 1, wherein the nanostructure is made of silicon material.

7. The method of claim 4, wherein the first DRIE is performed to form a scallop of wave pattern on the semiconductor substrate.

8. The method of claim 5, where the second DRIE is performed to faun nanotips on the semiconductor substrate.

9. The method of claim 4, wherein the deposition gas contains C₄F₈ gas.

10. The method of claim 4, wherein the etching gas contains SF₆ gas.

11. The method of claim 1, wherein the ARC contains silicon nitride.

12. The method of claim 1, wherein the ARC is formed via a plasma-enhanced chemical vapor deposition (PECVD).

13. The method of claim 1, wherein the front and back electrodes are formed by a printing.

14. A solar cell manufactured using the method according to claim 1.
